(19) United States
(12) Patent Application Publication
(10) Pub. No.: US 2013/0032948 A1
(43) Pub. Date: Feb. 7, 2013

(54) SEMICONDUCTOR DEVICE INCLUDING SUBSTRATE HAVING GROOVES

(71) Applicants: Chan PARK, Hwaseong-si (KR); Tae-Sung PARK, Cheonan-si (KR)

(72) Inventors: Chan PARK, Hwaseong-si (KR); Tae-Sung PARK, Cheonan-si (KR)

(21) Appl. No.: 13/523,189

(22) Filed: Jun. 14, 2012

(30) Foreign Application Priority Data
Aug. 1, 2011 (KR) 10-2011-0076600

(51) Int. Cl. H01L 23/488

(52) U.S. Cl. 257/774; 257/778; 257/E23.01; 257/E23.011

(57) ABSTRACT

A semiconductor device including a substrate having grooves is provided. The semiconductor device includes a substrate including a first surface, a second surface opposite to the first surface, an opening penetrating from the first surface to the second surface, and a first groove formed at a side of the opening, a semiconductor chip formed on the opening at the first surface of the substrate and flip-chip bonded to the first surface by a plurality of first external connection terminals, and a molding unit filling a region between the substrate and the semiconductor chip, filling the opening and filling at least a portion of the first groove, and covering the semiconductor chip.

### CROSS-REFERENCE TO RELATED APPLICATION

This application claims priority to Korean Patent Application No. 10-2011-0076600 filed on Aug. 1, 2011 in the Korean Intellectual Property Office under 35 U.S.C. 119, the contents of which are herein incorporated by reference in their entireties.

### TECHNICAL FIELD

Embodiments of the present inventive concept relate to a semiconductor device including a substrate having grooves.

### DISCUSSION OF THE RELATED ART

In a packaging process of a semiconductor device, a semiconductor chip may be bonded to a substrate and molded by a molding member, and external connection terminals may be then attached to ball lands formed on a bottom of the substrate.

When the semiconductor chip is molded, a “resin bleed” may occur that causes the molding member to bleed through a fine gap between the molding device and the substrate, thus resulting in contamination of the ball lands formed on the substrate.

### SUMMARY

Embodiments of the present inventive concept provide a semiconductor device including grooves in a substrate to prevent a molding member from oozing through the substrate, thus preventing ball lands from being contaminated due to the bleeding of the molding member.

According to an embodiment of the present inventive concept, there is provided a semiconductor device includes a substrate including a first surface, a second surface opposite to the first surface, an opening penetrating from the first surface to the second surface, and a first groove formed at a side of the opening, a semiconductor chip formed on the opening at the first surface of the substrate and flip-chip bonded to the first surface by a plurality of first external connection terminals, and a molding unit filling a region between the substrate and the semiconductor chip, filling the opening and filling at least a portion of the first groove, and covering the semiconductor chip.

According to an embodiment of the present inventive concept, there is provided a semiconductor device including a substrate including a first surface and a second surface opposite to the first surface, an opening penetrating from the first surface to the second surface, and first and second grooves formed on the second surface and spaced apart from each other, wherein the first and second grooves extend across the second surface in a first direction, the second surface is divided into first, second, and third regions by the first and second grooves, and the opening is formed in the second region, a semiconductor chip on the opening at the first surface of the substrate and flip-chip bonded to the first surface by a plurality of first external connection terminals, a plurality of second external connection terminals positioned on a the first and third regions, and a molding unit filling a region between the substrate and the semiconductor chip, filling the opening, filling at least a portion of the second region and filling at least portions of the first and second grooves, and covering the semiconductor chip.

### BRIEF DESCRIPTION OF THE DRAWINGS

The embodiments of the present inventive concept will become more apparent by the detail description with reference to the attached drawings in which:

FIG. 1 is a perspective view of a semiconductor device according to an embodiment of the present inventive concept;

FIG. 2 is a bottom view of the semiconductor device shown in FIG. 1;

FIG. 3 is a sectional view of the semiconductor device shown in FIG. 2, taken along the line A-A;

FIG. 4 is a perspective view of a substrate included in the semiconductor device shown in FIG. 1;

FIG. 5 is a bottom view of the substrate shown in FIG. 4;

FIG. 6 is a sectional view of the semiconductor device shown in FIG. 2, taken along the line B-B′;

FIGS. 7 and 8 are sectional views of intermediate structures for illustrating a molding process of the semiconductor device shown in FIG. 1;

FIG. 9 is a sectional view of a semiconductor device according to an embodiment of the present inventive concept;

FIG. 10 is a bottom view of a semiconductor device according to an embodiment of the present inventive concept;

FIG. 11 is a perspective view of a substrate included in a semiconductor device according to an embodiment of the present inventive concept;

FIG. 12 is a bottom view of the semiconductor device shown in FIG. 12;

FIG. 13 is a sectional view of a semiconductor device according to an embodiment of the present inventive concept;

FIG. 14 is a plan view of a semiconductor system according to an embodiment of the present inventive concept;

FIG. 15 is a block diagram of a semiconductor system according to an embodiment of the present inventive concept;

FIG. 16 is a block diagram of a semiconductor system according to an embodiment of the present inventive concept; and

FIG. 17 illustrates an example of an electronic device including the semiconductor system shown in FIG. 16.

### DETAILED DESCRIPTION OF THE EMBODIMENTS

The embodiments of the present inventive concept may be understood more readily by reference to the following detailed description and the accompanying drawings. The embodiments of the present inventive concept may, however, be embodied in many different forms and should not be construed as being limited to the embodiments set forth herein. In the drawings, the thickness of layers and regions may be exaggerated for clarity.

It will be understood that when an element or layer is referred to as being “connected to,” or “coupled to” another element or layer, it can be directly connected to or coupled to another element or layer or intervening elements or layers may be present.

As used herein, the singular forms “a”, “an” and “the” are intended to include the plural forms as well, unless the context clearly indicates otherwise.

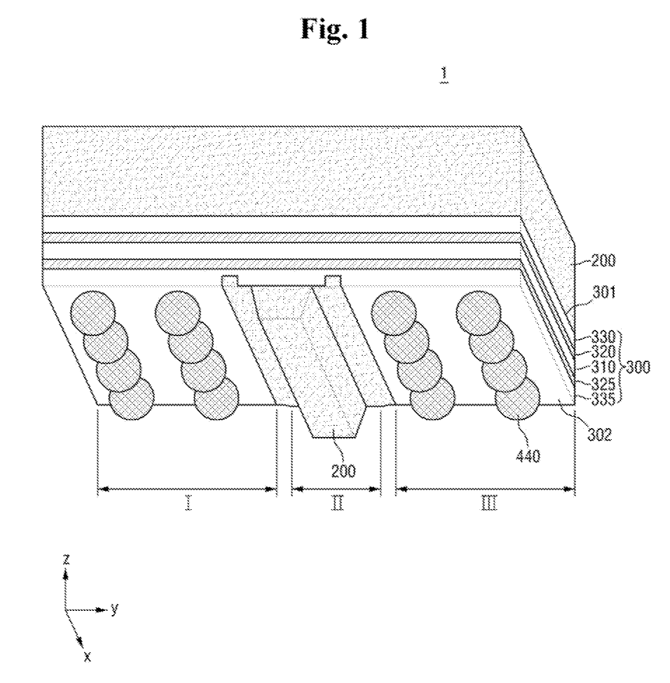

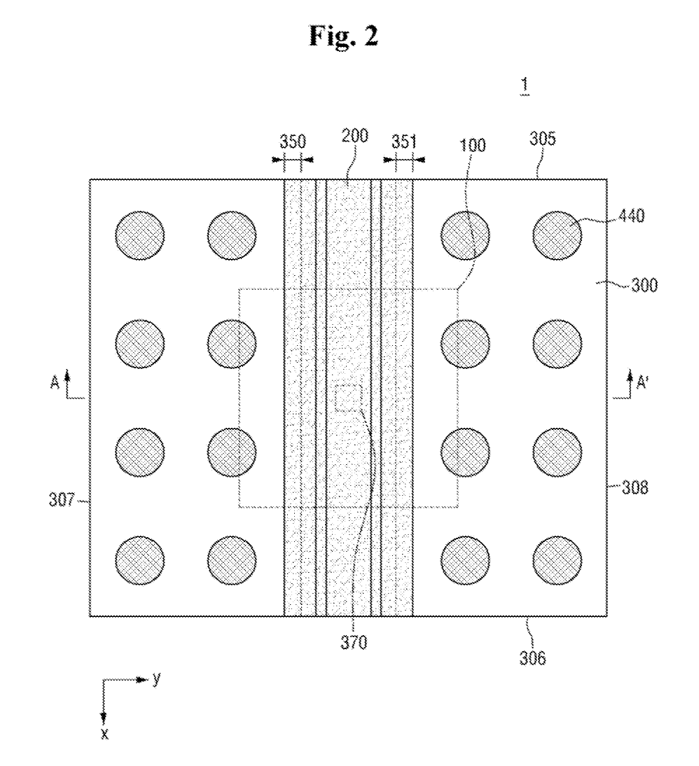

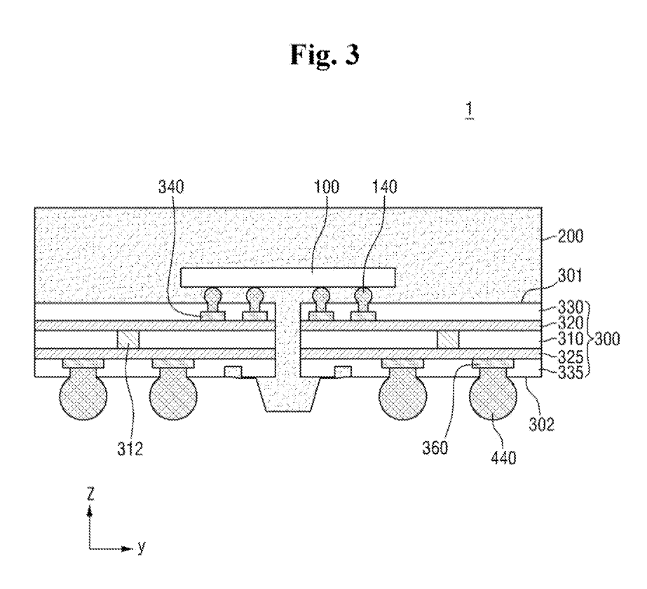

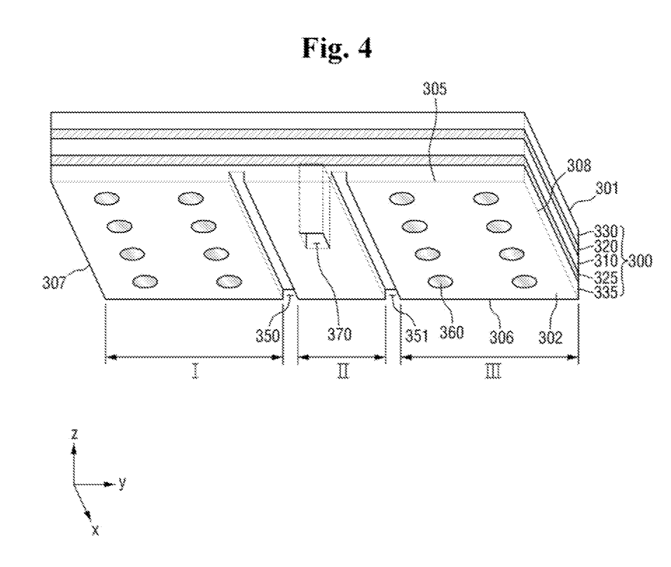

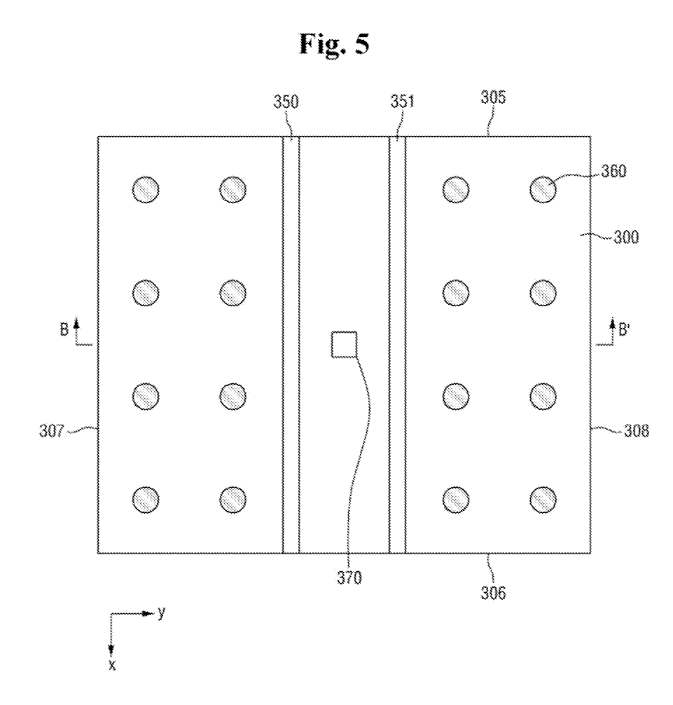

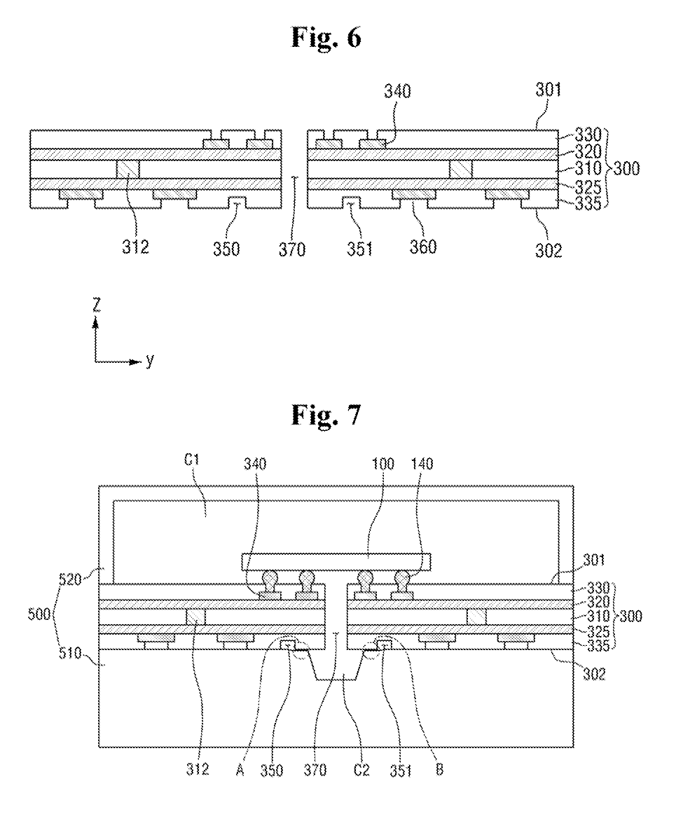

Hereinafter, a semiconductor device according to an embodiment of the present inventive concept will be described with reference to FIGS. 1 to 6. FIG. 1 is a perspective view of a semiconductor device according to an embodiment of the present inventive concept, FIG. 2 is a bottom view of the semiconductor device shown in FIG. 1, FIG. 3 is a sectional view of the semiconductor device shown in FIG. 2, taken along the line A-A′, FIG. 4 is a perspective view of a substrate included in the semiconductor device shown in FIG. 1, FIG. 5 is a bottom view of the substrate shown in FIG. 4, and FIG. 6 is a sectional view of the semiconductor device shown in FIG. 2, taken along the line B-B′.

Referring to FIGS. 1 to 3, the semiconductor device 1 includes a substrate 300, a semiconductor chip 100 positioned on the substrate 300, and a molding unit 200 molding the semiconductor chip 100.

The semiconductor chip 100 is positioned on a first surface 301 of the substrate 300. In detail, the semiconductor chip 100 is positioned on an opening 370 of the substrate 300, and the semiconductor chip 100 overlaps the opening 370 of the substrate 300.

The semiconductor chip 100 is bonded to the first surface 301 of the substrate 300 by flip chip bonding through first external connection terminals 140. The semiconductor chip 100 is electrically connected to the substrate 300 through the first external connection terminals 140. As shown in FIGS. 1 to 3, each first external connection terminal 140 includes a conductive ball or a solder ball, but not limited thereto. For example, according to an embodiment, the first external connection terminal 140 includes one of a conductive bump, a conductive spacer, or a pin grid array (PGA).

The semiconductor chip 100 is formed of silicon, silicon on insulator (SOI), or silicon germanium, but not limited thereto. The semiconductor chip 100 includes, for example, multi-layered wirings, a plurality of transistors, or a plurality of passive elements.

Referring to FIGS. 4 to 6, the substrate 300 includes an insulation layer 310, first and second wiring layers 320 and 325, first and second passivation layers 330 and 335, an opening 370, first and second grooves 350 and 351, and first and second ball lands 340 and 360.

The substrate 300 includes first and second wiring layers 320 and 325 respectively formed on two surfaces of the insulation layer 310, and first and second passivation layers 330 and 335 formed on the first and second wiring layers 320 and 325, respectively. For example, the insulation layer 310 and the first and second wiring layers 320 and 325 constitute a copper clad laminate (CCL), but not limited thereto. The embodiments of the inventive concept are not limited to the laminate structure of the substrate 300.

Circuit patterns are formed on the first and second wiring layers 320 and 325. The first wiring layer 320 is electrically connected to the second wiring layer 325 through, for example, conductive vias 312. The first and second passivation layers 330 and 335 are formed of a material including, for example, photo solder resist (PSR).

A surface of the substrate 300, which is positioned on the first passivation layer 330, is defined as a first surface 301, and a surface of the substrate 300, which is positioned on the second passivation layer 335, is defined as a second surface 302. The first and second surfaces 301 and 302 are different surfaces, and the second surface 302 is positioned opposite to the first surface 301. Four edges surrounding the second surface 302 of the substrate 300 are defined as first to fourth edges 305, 306, 307 and 308, respectively. The first and second edges 305 and 306 are positioned to be opposite to each other, and the third and fourth edges 307 and 308 are positioned to be opposite to each other.

The opening 370 penetrates the substrate 300 from the first surface 301 to the second surface 302. For example, the opening 370 includes a slit. A cross section of the opening 370 is rectangular, but not limited thereto. According to an embodiment, the cross section of the opening 370 is circular.

The first and second grooves 350 and 351 are formed on the second surface 302 of the substrate 300. The first and second grooves 350 and 351 extend across the second surface 302 in a first direction (i.e., in the X direction). In detail, the first and second grooves 350 and 351 are parallel to each other and extend from the first edge 305 to the second edge 306 of the second surface 302. Lengths of the first and second grooves 350 and 351 in the first direction are equal to a length of the substrate 300 in the first direction.

The first and second grooves 350 and 351 are formed at two sides of the opening 370. In detail, the first and second grooves 350 and 351 are spaced apart from the opening 370 by a predetermined distance.

The first and second grooves 350 and 351 are formed by removing portions of the second passivation layer 335. For example, depths of the first and second grooves 350 and 351 are smaller than a thickness of the second passivation layer 335. According to an embodiment, the second wiring layer 325 is not exposed through the first and second grooves 350 and 351. However, when the portions of the second passivation layer 335 are excessively removed in the course of forming the first and second grooves 350 and 351, a portion of the second wiring layer 325 may be slightly exposed through the first and second grooves 350 and 351. Referring to FIG. 3, the first and second grooves 350 and 351 are filled by the molding unit 200. Even when the portion of the second wiring layer 325 is slightly exposed through the first and second grooves 350 and 351, the second wiring layer 325 can be protected by the molding unit 200, thereby preventing the reliability of the semiconductor device 1 from deteriorating.

Referring back to FIGS. 4 to 6, the first and second grooves 350 and 351 can prevent the molding unit (200 of FIG. 1) from oozing along the second surface 302 to the second ball lands 360 in a subsequent molding process of the semiconductor device 1. For example, since the molding unit 200 is stuck in the first and second grooves 350 and 351, the molding unit 200 may be suppressed from further flowing to the ball lands 360, thereby preventing the second ball lands 360 from being contaminated by the molding unit 200.

Referring to FIG. 4, the second surface 302 of the substrate 300 is divided into first to third regions I, II and III by the first and second grooves 350 and 351. In detail, a region of the second surface 302 between the first groove 350 and the third edge 307 is defined as the first region I. A region of the second surface 302 between the first groove 350 and the second groove 351 is defined as the second region II. A region of the second surface 302 between the second groove 351 and the fourth edge 308 is defined as the third region III. For example, the second ball lands 360 are formed on the first and third regions I and III, and the opening 370 is formed on the second region II.

Referring to FIGS. 3 and 6, the first and second ball lands 340 and 360 are formed at the first and second surfaces 301 and 302, respectively, of the substrate 300. The first and second ball lands 340 and 360 are electrically connected to the first and second wiring layers 320 and 325, respectively. The first ball lands 340 are positioned at two sides of the opening 370 and are connected to the first external connection terminals 140. The second ball lands 360 are formed on the first and third regions I and III of the second surface 302. The second ball lands 360 are positioned at a side surface of the first groove 350 and at a side surface of the second groove 351. Since the second ball lands 360 are positioned at the side surfaces of the first and second grooves 350 and 351, the molding unit 200 is suppressed from reaching the second ball lands 360 by the first and second grooves 350 and 351, thereby preventing contamination of the second ball lands 360.

Referring to FIGS. 1 to 3, second external connection terminals 440 are positioned on the second ball lands 360 and contact the second ball lands 360. However, the second external connection terminals 440 are not positioned on the first and second grooves 350 and 351. The second external connection terminals 440 are positioned on the first and third regions I and III of the second surface 302.

The molding unit 200 molds the semiconductor chip 100 on the first surface 301 of the substrate 300. The molding unit 200 includes, but not limited to, an epoxy mold compound (EMC) as a molding member.

The molding unit 200 fills a region between the substrate 300 and the semiconductor chip 100, fills the opening 370, and fills at least a portion of the second region II of the second surface 302 of the substrate 300 and covers the semiconductor chip 100. For purposes of the description, the molding unit 200 is divided into three regions, e.g., first, second, and third regions. According to an embodiment, all the regions of the molding unit 200 are formed of the same molding member.

The first region of the molding unit 200 is formed on the first surface 301 of the substrate 300. The molding unit 200 surrounds the semiconductor chip 100 and fills a space between the first surface 301 of the substrate 300 and the semiconductor chip 100. The molding unit 200 fills spaces between adjacent ones of the first external connection terminals 140. As a consequence, the molding unit 200 functions as a molding member for molding the semiconductor chip 100 and as an underfill member for reinforcing adhesion of the first external connection terminals 140.

The second region of the molding unit 200 fills the opening 370 of the substrate 300. According to an embodiment of the present inventive concept, the semiconductor chip 100 is bonded to the first surface 301 of the substrate 300 by flip chip bonding. The semiconductor chip 100 is electrically connected to the first surface 301 of the substrate 300 through, for example, the first external connection terminals 140. The first wiring layer 320 and the second wiring layer 325 are electrically connected to each other through the conductive via 312. Therefore, the semiconductor chip 100 is electrically connected to the second surface 302 through the first external connection terminals 140, the first wiring layer 320, the conductive via 312, and second wiring layer 325, eliminating the need of wires for connecting the semiconductor chip 100 and the second surface 302 of the substrate 300 through the opening 370 of the substrate 300. The opening 370 of the substrate 300 is filled by the molding unit 200.

The third region of the molding unit 200 is formed on the second surface 302 of the substrate 300. The molding unit 200 covers at least a portion of the second region II of the second surface 302 and fills at least portions of the first and second grooves 350 and 351. For example, the molding unit 200 covers the opening 370 and protrudes from the second surface 302. The molding unit 200 extends to the first and second grooves 350 and 351 and fills at least portions of the first and second grooves 350 and 351. However, the molding unit 200 does not reach the second ball lands 360 past the first and second grooves 350 and 351.

The molding unit 200 extends across the second surface 302 in the first direction (e.g., in the X direction) and covers the opening 370 of the second surface 302. For example, the molding unit 200 extends from the first edge 305 to the second edge 306 of the second surface 302 in parallel with the first and second grooves 350 and 351. A length of a region of the molding unit 200 positioned on the second surface 302 in the first direction is equal to lengths of the first and second grooves 350 and 351 in the first direction.

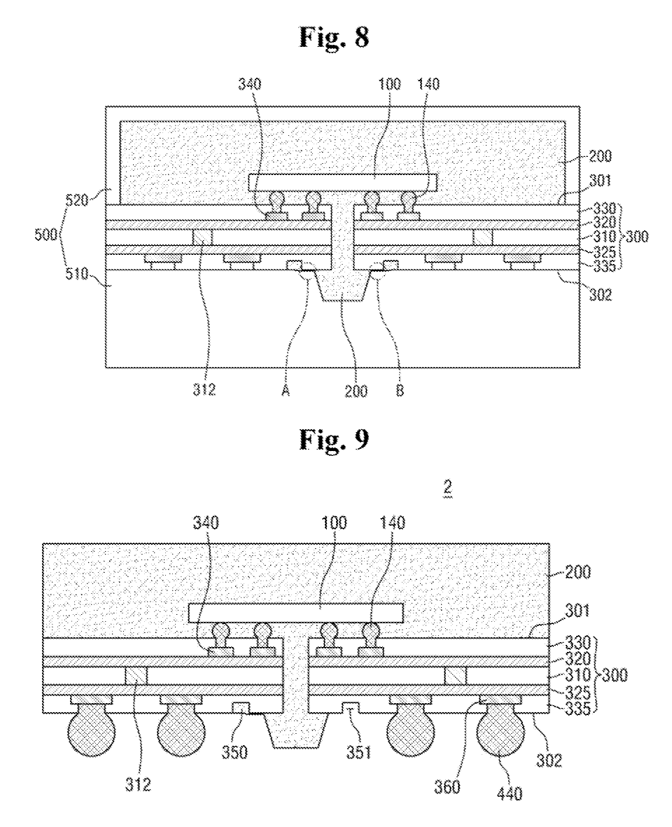

A molding process of the semiconductor device according to an embodiment shown in FIG. 1 is described with reference to FIGS. 7 and 8. FIGS. 7 and 8 are sectional views of intermediate structures for illustrating a molding process of the semiconductor device shown in FIG. 1.

Referring to FIG. 7, a molding device 500 includes a top mold 520 and a bottom mold 510. The substrate 300 having the semiconductor chip 100 mounted on the first surface 301 is loaded into the molding device 500. The substrate 300 is clamped by the top mold 520 and the bottom mold 510. A first cavity C1 is formed to be surrounded by the first surface 301 of the substrate 300 and the top mold 520, and a second cavity C2 is formed to be surrounded by the second surface 302 of the substrate 300 and the bottom mold 510.

Referring to FIG. 8, a molding member is injected into the first cavity C1. The injected molding member moves through the opening 370 of the substrate 300 and fills the second cavity C2. The opening 370 of the substrate 300 functions as a path through which the molding member injected into the first cavity C1 moves to the second cavity C2. The second cavity C2 is filled with the molding member and the opening 370 of the substrate 300 is then filled with the molding member. The first cavity C1 is finally filled with the molding member. For example, a space between the semiconductor chip 100 and the first surface 301 of the substrate 300 is underfilled by the molding member, and the semiconductor chip 100 is covered by the molding member. A region between adjacent first external connection terminals of the first external connection terminals 140 is filled with the molding member. As a result, molding and underfilling are simultaneously performed by a molding process.

The molding members filling the first and second cavities C1 and C2 and the opening 370 of the substrate 300 are cured, thereby forming the molding unit 200. The molding unit 200 fills the region between the semiconductor chip 100 and the substrate 300, fills the opening 370 and fills at least a portion of the second region II of the second surface 302 of the substrate 300 and covers the semiconductor chip 100. All of the regions of the molding unit 200 are formed by the same molding member.

However, as shown in FIGS. 7 and 8, fine gaps on the regions A and B may exist between the bottom mold 510 and the second surface 302 of the substrate 300. The molding member filling the second cavity C2 may ooze through the fine gaps. However, the oozing molding member is stuck in the first and second grooves 350 and 351, thus preventing the molding member from further spreading to, e.g., the first and second grooves 350 and 351. Thus, the second ball lands 360 positioned on the side surfaces of the first and second grooves 350 and 351 can be prevented from being contaminated. The molding unit 200 fills at least portions of the first and second grooves 350 and 351 but does not extend to the second ball lands 360 over the first and second grooves 350 and 351.

By blocking the spread of the molding member, the first and second grooves 350 and 351 also prevents contamination of the bottom mold 510 due to the molding member. Thus, a cleaning time of the bottom mold 510 can be shortened, thereby improving the productivity of the semiconductor device 1.

A semiconductor device according to an embodiment of the present inventive concept is described with reference to FIG. 9. The following description focuses on differences from the semiconductor device described in connection with FIGS. 1 to 8. FIG. 9 is a sectional view of a semiconductor device according to an embodiment of the present inventive concept.

Referring to FIG. 9, a molding unit 200 in the semiconductor device 2 does not fill a second groove 351, unlike the semiconductor device 1 shown in FIG. 3. For example, according to an embodiment, a gap created in a region (e.g., region B of FIG. 7) between a bottom mold 510 and a second surface 302 of a substrate 300 when the semiconductor device 2 is molded may be too small for a molding member to flow through. Thus, the molding member filling a second cavity C2 does not reach the second groove 351, not filling the second groove 351.

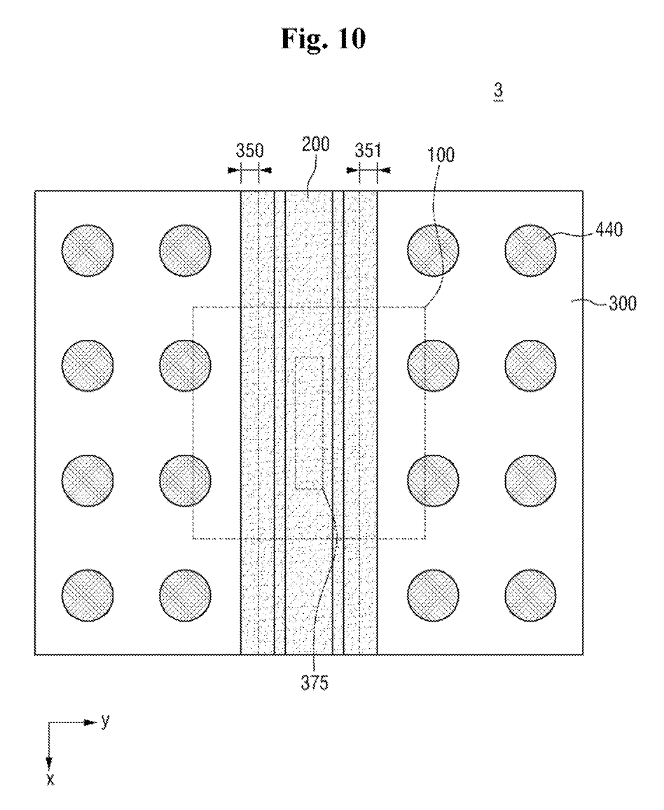

A semiconductor device according to an embodiment of the present inventive concept is described with reference to FIG. 10. The following description focuses on differences from the semiconductor device described in connection with FIGS. 1 to 8.

FIG. 10 is a bottom view of a semiconductor device according to an embodiment of the present inventive concept.

Referring to FIG. 10, an opening 375 in the semiconductor device 3 includes a slit, and a length of the opening 375 in a first direction (e.g., in the X direction) is smaller than a length of a semiconductor chip 100 in the first direction unlike the semiconductor device 1 of FIG. 2. However, the embodiments of the inventive concept are not limited thereto. For example, alternatively, the length of the opening 375 in the first direction is greater than the length of the semiconductor chip 100 in the first direction.

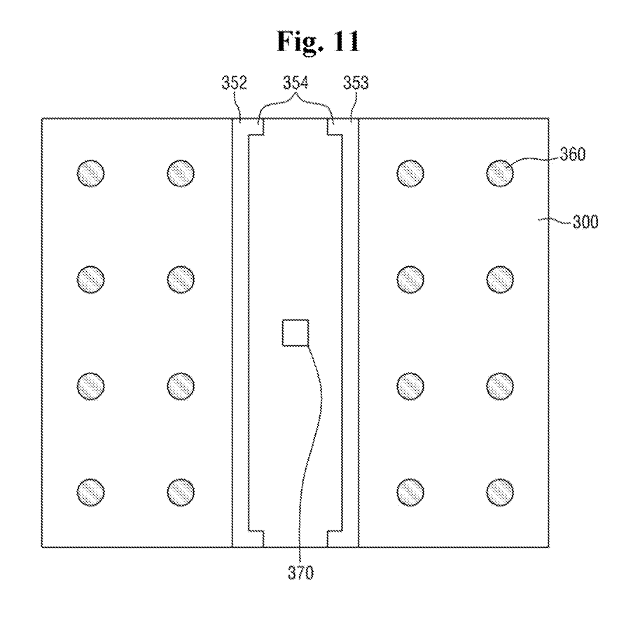

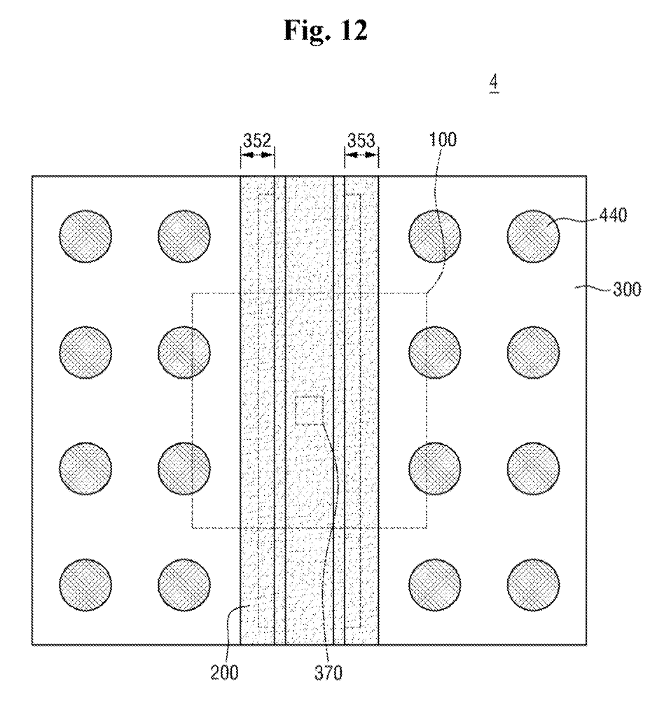

A semiconductor device according to an embodiment of the present inventive concept is described with reference to FIGS. 11 and 12. The following description focuses on differences from the semiconductor device described in connection with FIGS. 1 to 8. FIG. 11 is a perspective view of a substrate included in a semiconductor device according to an embodiment of the present inventive concept, and FIG. 12 is a bottom view of the semiconductor device shown in FIG. 12.

Referring to FIGS. 11 and 12, a substrate 300 of the semiconductor device 4 includes third and fourth grooves 352 and 353 which are different in shape from the first and second grooves 350 and 351 of the semiconductor device 1 as shown in FIG. 2. Each of the third and fourth grooves 352 and 353 includes a protruding region 354. The protruding region 354 of the third groove 352 and the protruding region 354 of the fourth groove 353 are formed to face each other, but not limited thereto. Since each of the third and fourth grooves 352 and 353 includes the protruding region 354, the amount of the molding member accommodated in the grooves 352 and 353 increases.

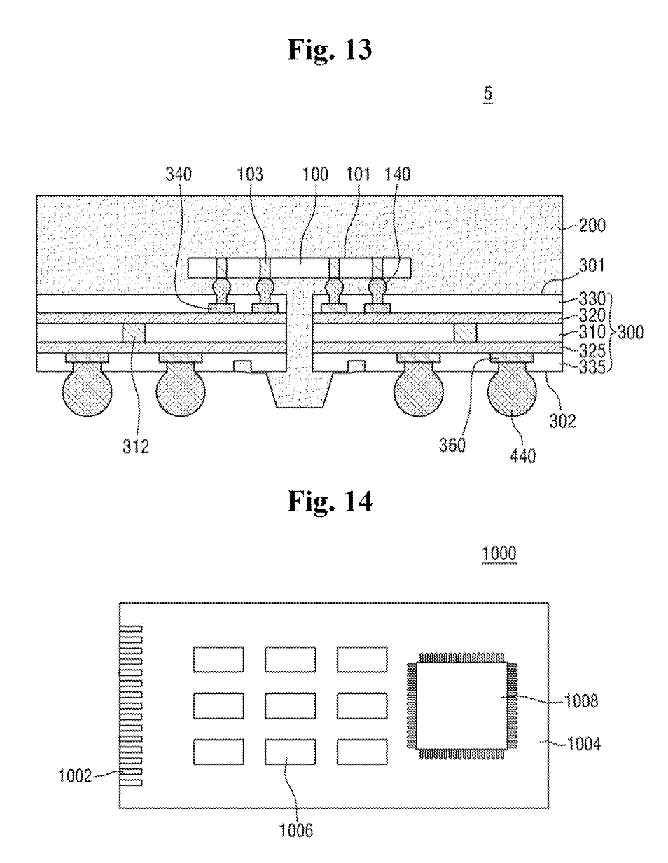

A semiconductor device according to an embodiment of the present inventive concept is described with reference to FIG. 13. However, the following description focuses on differences from the semiconductor device described in connection with FIGS. 1 to 8. FIG. 13 is a sectional view of a semiconductor device according to an embodiment of the present inventive concept.

Referring to FIG. 13, penetration electrodes 103 are formed in a semiconductor chip 100. Each penetration electrode 103 is, for example, a through silicon via. The penetration electrodes 103 are formed to penetrate the semiconductor chip 100 from a surface to another surface of the semiconductor chip 100.

Therefore, the semiconductor chip 100 of the semiconductor device 5 is not bonded by flip chip bonding unlike the semiconductor device 1 of FIG. 3. In detail, the semiconductor chip 100 is electrically connected to a first surface 301 of a substrate 300 through first external connection terminals 140 like in the semiconductor device 1. For example, circuit patterns are formed on a top surface 101 of the semiconductor chip 100. The circuit patterns formed on the top surface 101 of the semiconductor chip 100 are electrically connected to the first external connection terminals 140 through the penetration electrodes 103.

Semiconductor systems according to embodiments of the present inventive concept are described with reference to FIGS. 14 to 17.

FIG. 14 is a plan view of a semiconductor system according to an embodiment of the present inventive concept.

Referring to FIG. 14, the semiconductor system 1000 includes a package module.

The semiconductor system 1000 includes a module substrate 1004 having external connection modules 1002, and semiconductor devices 1006 and 1008. A packaging technique of the semiconductor device 1008 includes, for example, QFP (Quad Flat Package), but not limited thereto. The semiconductor devices 1006 and 1008 each include at least one of the semiconductor devices shown in FIGS. 1 to 13. For example, each of the semiconductor devices 1006 and 1008 includes a substrate having a first surface, a second surface positioned opposite to the first surface, an opening penetrating from the first surface to the second surface, and a first groove formed in the second surface at a side of the opening, a semiconductor chip formed on the opening of the first surface of the substrate, and a molding unit filling a region between the substrate and the semiconductor chip, filling the opening and filling at least a portion of the first groove and covering the semiconductor chip.

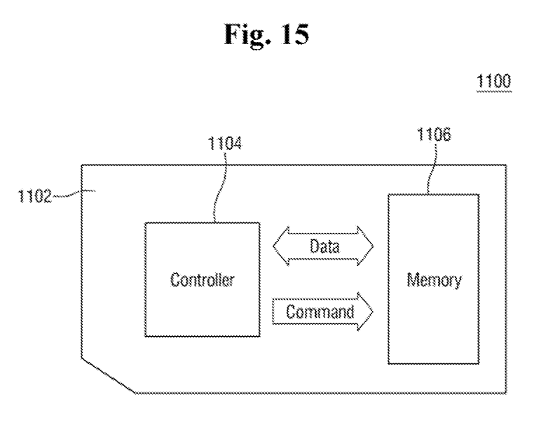

FIG. 15 is a block diagram of a semiconductor system according to an embodiment of the present inventive concept.

Referring to FIG. 15, the semiconductor system 1100 includes a memory card. The semiconductor system 1100 includes a controller 1104 and a memory 1106 in a housing 1102. The controller 1104 and the memory 1106 exchange electrical signals. For example, the memory 1106 and the controller 1104 transmit and receive data in accordance with a command of the controller 1104. Accordingly, the semiconductor system 1100 stores data in the memory 1106 or outputs data from the memory 1106 to an outside device. The controller 1104 and the memory 1106 include at least one of the semiconductor devices shown in FIGS. 1 to 13.

The semiconductor system 1100 is used as a data storage medium in a variety of portable devices. For example, the semiconductor system 1100 includes a multimedia card (MMC) or a secure digital (SD) card.

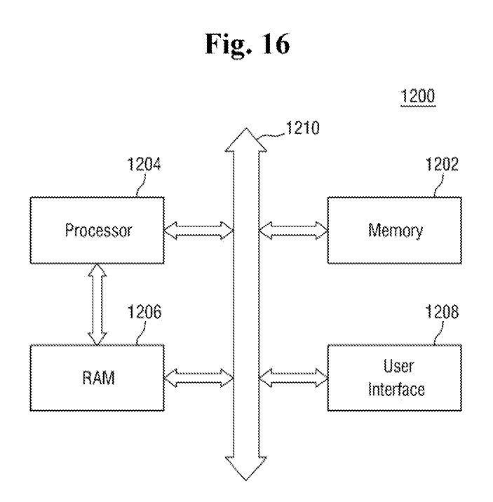

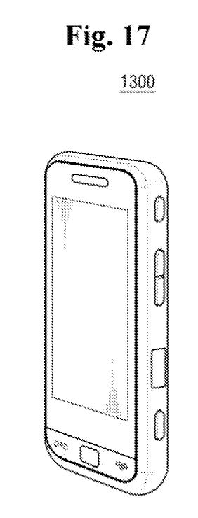

FIG. 16 is a block diagram of a semiconductor system according to an embodiment of the present inventive concept, and FIG. 17 illustrates an example of an electronic device including the semiconductor system shown in FIG. 16.

Referring to FIG. 16, the semiconductor system 1200 includes a memory system 1202, a processor 1204, a random access memory (RAM) 1206, and a user interface 1208, and performs data communication using a bus 1210. The processor 1204 executes a program and controls the semiconductor system 1200. The RAM 1206 is used as an operation memory of the processor 1204. The processor 1204 and the RAM 1206 are included in a single package. For example, a logic chip including the processor 1204 and a memory chip including the RAM 1206 are included in a system in package (SIP) and wirelessly communicate with each other. The user interface 1208 is used to input or output data to/from the semiconductor system 1200. The memory system 1202 stores codes for operating the processor 1204, data processed by the processor 1204, externally applied data, and so on. The memory system 1202 includes a controller and a memory. The memory system 1202 is configured in substantially the same as or similar to the memory card 1100 shown in FIG. 15.

The semiconductor system 1200 is applied to electronic control devices of various electronic devices. For example, the semiconductor system 1200 is applied to a mobile phone 1300 of FIG. 17. The semiconductor system 1200 is applied to portable game devices, portable notebook computers, MP3 players, navigation devices, solid state disks (SSDs), automobiles, or household appliances.

While the embodiments of the present inventive concept have been particularly shown and described, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A semiconductor device comprising:
a substrate including a first surface, a second surface opposite to the first surface, an opening penetrating from the first surface to the second surface, and a first groove at a side of the opening on the second surface;
a semiconductor chip formed on the opening at the first surface of the substrate, wherein the semiconductor chip is flip-chip bonded to the first surface by a plurality of first external connection terminals; and
a molding unit filling a region between the substrate and the semiconductor chip, filling the opening, and filling at least a portion of the first groove and covering the semiconductor chip.

2. The semiconductor device of claim 1, wherein the substrate further comprises a passivation layer, and the first groove is formed by removing a portion of the passivation layer.

3. The semiconductor device of claim 1, wherein the first groove is spaced apart from the opening.

4. The semiconductor device of claim 1, wherein the molding unit fills a region between adjacent first external connection terminals of the first external connection terminals.

5. The semiconductor device of claim 1, wherein the opening is filled with the molding unit.

6. The semiconductor device of claim 1, wherein the substrate further comprises a second groove formed on the second surface at another side of the opening, wherein the opening is positioned between the first groove and the second groove, and wherein the molding unit fills at least a portion of the second groove.

7. The semiconductor device of claim 1, wherein the first groove extends across the second surface in a first direction.

8. The semiconductor device of claim 1, wherein the molding unit extends across the second surface in a first direction and covers the opening at the second surface.

9. The semiconductor device of claim 1, wherein a length of the first groove in a first direction is equal to a length of the substrate in the first direction.

10. The semiconductor device of claim 1, wherein the overall molding unit includes a same molding member.

11. A semiconductor device comprising:
a substrate including,
a first surface and a second surface opposite to the first surface,
an opening penetrating from the first surface to the second surface, and
first and second grooves formed on the second surface, wherein the first and second grooves are spaced apart from each other and extend across the second surface in a first direction, and wherein the second is divided into first, second, and third regions by the first and second grooves, and the opening is formed in the second region;
a semiconductor chip formed on the opening at the first surface of the substrate, wherein the semiconductor chip is flip-chip bonded to the first surface by a plurality of first external connection terminals;
a plurality of second external connection terminals positioned in the first and third regions; and
a molding unit filling a region between the substrate and the semiconductor chip, filling the opening, filling at least a portion of the second region, and filling at least portions of the first and second grooves and covering the semiconductor chip.

12. The semiconductor device of claim 11, wherein the substrate includes a passivation layer, and the first and second grooves are formed by removing a portion of the passivation layer.

13. The semiconductor device of claim 11, wherein the first and second grooves are spaced apart from the opening.

14. The semiconductor device of claim 11, wherein lengths of the first and second grooves in the first direction are equal to a length of the substrate in the first direction.

15. The semiconductor device of claim 11, wherein the first region is defined between an end of the second surface and the first groove, the second region is defined between the first groove and the second groove, and the third region is defined between the other end of the second surface and the second groove.

16. The semiconductor device of claim 11, wherein the molding unit fills a region between adjacent first external connection terminals of the first external connection terminals.

17. A semiconductor device comprising:
a substrate including,
a first surface,
a second surface opposite to the first surface,
an opening penetrating the substrate from the first surface to the second surface, and
at least one groove at a side of the opening on the second surface;
a molding unit including,
a first region covering the first surface of the substrate,
a second region filling the opening of the substrate, and
a third region covering a portion of the second surface of the substrate; and
a semiconductor chip positioned in the first region of the molding unit, wherein the semiconductor chip is bonded to the substrate by at least one first external connection terminal.

18. The semiconductor device of claim 17, wherein the opening of the substrate is shaped as a slit that is elongated in a direction.

19. The semiconductor device of claim 17, wherein the at least one groove of the substrate extends across the second surface of the substrate in a first direction and includes an extension protruding in a second direction perpendicular to the first direction.

20. The semiconductor device of claim 17, wherein the semiconductor chip includes at least one penetration electrode penetrating the semiconductor chip, wherein the at least one penetration electrode is connected to the at least one first external connection terminal.
